(19) United States
(12) Patent Application Publication
(10) Pub. No.: US 2026/0330090 A1
(43) Pub. Date: Oct. 22, 2026

(54) WIRELESS SIGNAL IDENTIFICATION OF BARRIER PROPERTIES

(71) Applicant: PassiveLogic, Inc., Holladay, UT (US)

(72) Inventors: Mahan TABATABAIE, Holladay, UT (US); Porter Jonas CHILD, Holladay, UT (US)

(21) Appl. No.: 19/183,229

(22) Filed: Apr. 18, 2025

Related U.S. Application Data
(60) Provisional application No. 63/785,498, filed on Apr. 8, 2025.

(51) Int. Cl. G06F 30/20; H04B 17/318; H04B 17/391

(52) U.S. Cl. CPC G06F 30/20; H04B 17/318; H04B 17/3912

(57) ABSTRACT

Some embodiments leverage radiofrequency signal strength data to improve the accuracy of barrier thermal representations in thermal flow scenarios. Walls, floors, ceilings, windows, equipment, and furnishings are examples of barriers in a building. Barrier properties such as composition material and thickness are computed from radiofrequency signal strength data, and then corresponding radiofrequency or thermal characteristics are utilized, e.g., to tune a neural network or other thermal flow simulation, or to operate a heating or cooling controller. A barrier belonging to a group is conformed in some cases to a shared property value of the group. Threshold condition tests are employed in some cases to select between material value changes and thickness value changes.

### RELATED APPLICATION

The present application claims priority to, and incorporates by reference the entirety of, U.S. provisional patent application No. 63/785,498 filed 8 Apr. 2025.

### BACKGROUND

Building automation systems are used in buildings to manage energy systems such as Heating, Ventilation, and Air Conditioning (HVAC) systems in buildings. Trying to model buildings accurately and efficiently to improve HVAC system operation is challenging. Even a single-floor building with only a dozen rooms will pose many questions about what data to model, how to represent the building and its constituent parts in a simulation, and how to compare simulated behavior and simulated characteristics to actual physical behavior and physical characteristics.

### TECHNICAL FIELD

The present application relates to Heating, Ventilation, and Air Conditioning (HVAC), and more specifically to simulations used to model or manage HVAC system operation in a building.

### SUMMARY

Some embodiments address technical challenges arising from efforts to accurately and efficiently represent walls, windows, equipment, and other barriers in a simulation of a building. HVAC simulations depend on information about barriers in order to compute heat flows to and from different areas of a building. One challenge is how to approximate barrier thickness and barrier material using sensors, when blueprints, permits, and other architectural or construction materials are not sufficient sources of such barrier data. Another challenge is how to tune the simulation in order to update barrier thickness or barrier material based on sensed data. other technical challenges are also addressed herein.

Some example embodiments taught herein compute a barrier property value from at least two sensed radiofrequency signal strength values, the barrier property value representing a barrier material or a barrier thickness, and utilize the barrier property value in at least one of: executing a computational simulation of heat transfer which employs a digital representation of a building, tuning the computational simulation, or operating a heating control mechanism which controls heating of a physical building. Details are explored in various embodiments discussed herein.

Additional technical activities, technical characteristics, and technical benefits pertinent to teachings herein will also become apparent to those of skill in the art. The examples given are merely illustrative. This Summary is not intended to identify key features or essential features of the claimed subject matter, nor is it intended to be used to limit the scope of the claimed subject matter. Rather, this Summary is provided to introduce-in a simplified form some technical concepts that are further described below in the Detailed Description. Subject matter scope is defined with claims as properly understood, and to the extent this Summary conflicts with the claims, the claims should prevail.

### BRIEF DESCRIPTION OF THE DRAWINGS

A more particular description will be given with reference to the attached drawings. These drawings only illustrate selected aspects and thus do not fully determine coverage or scope.

FIG. 1 is a block diagram illustrating some aspects of a computer system, including some aspects generally suitable for enhanced systems which include or use wireless signal identification of barrier properties (WSIBP) functionality;

FIG. 2 is a diagram illustrating some aspects of a building;

FIG. 3 is a block diagram illustrating some aspects of radiofrequency (RF) signals;

FIG. 4 is a block diagram illustrating some aspects of barriers in a building;

FIG. 5 is a block diagram illustrating some aspects of WSIBP values;

FIG. 6 is a block diagram illustrating some aspects of sensors;

FIG. 7 is a first flowchart illustrating some WSIBP methods;

FIG. 8 is a second flowchart illustrating some WSIBP methods;

FIG. 9 is a third flowchart illustrating some WSIBP methods; and

FIG. 10 is a flowchart further illustrating WSIBP methods, and incorporating as options the steps of FIGS. 7 through 9, and other steps disclosed herein; and

FIG. 11 illustrates an example digital twin.

### DETAILED DESCRIPTION

### Overview

Knowing material properties can be helpful for estimating heat transfer and thus predicting the temperature of a room in a building. For instance, if an exterior wall of the room is made of concrete, then the amount of sunlight heat passing through that wall is different that it would be if the wall was made of brick. The accuracy of a building model's predictions of heat transfer and temperature can affect HVAC system actions, e.g., cooling control actions or heating control actions. The more accurately a simulation of the building can estimate the future temperature of a building zone, the more efficiently the HVAC system can perform to regulate the temperature in that zone in line with targets (human comfort level, electrical power usage, server computer internal temperature, etc.).

However, it is challenging to obtain accurate data describing the material and related properties of every wall and other thermal barrier in a given building. Modeling and other simulation accordingly will sometimes start with an initial guess, and some effort will be made to refine the description of the wall over time.

One approach to the problem of obtaining accurate data describing the material (concrete, brick, etc.) and related properties (e.g., thickness) of a wall is to categorize the building. For example, one approach would categorize the building according to the building's age and the building's city or other geographic location, and then adopt a corresponding predefined description of the building's walls. Age and geographic location are two examples of characteristics which are usable to define a building category, but other characteristics could also be used in addition or instead, e.g., the type of building (office, hospital, school, data center, factory, etc.), or the property zoning ordinances that apply to the building. However, this building categorization approach will mis-describe buildings that are atypical for the category in question. It will also mis-describe portions of buildings which are atypical, even when the building overall fits within the category.

Another approach to the problem of obtaining accurate wall property descriptions is to infer an approximation from blueprints, permits, or other architectural or construction documents. However, such documents are not always available, and are not always accurate and complete even when they are available. A permit, for example, does not necessarily describe the material and the thickness of each wall or other barrier whose construction or modification the permit covers.

A third approach is to have humans inspect the walls and manually enter their observations into a database for later access by the building simulation. However, this inspection-by-a-human approach is very human-labor-intensive and thus expensive. Moreover, this approach is not possible when human inspectors are denied entry to the walled area, due to safety, confidentiality, regulatory, or other constraints. In addition, this approach will not account for new walls or wall modifications which occurred after the human inspection was completed.

Some embodiments described herein take a different approach, referred to here as wireless signal identification of barrier properties (WSIBP). Some embodiments described herein utilize or provide a WSIBP method performed by a computing system. This WSIBP method includes: collecting two sensed signal strength values of a radiofrequency signal; computing a barrier property value from at least the two sensed signal strength values, the barrier property value representing a barrier material or a barrier thickness; and utilizing the barrier property value in at least one of: executing a computational simulation of heat transfer which employs a digital representation of a building, or operating a heating control mechanism which controls heating of a physical building.

This WSIBP functionality has a technical benefit of increasing the accuracy of barrier property descriptions in a model, relative to actual physical properties of a corresponding physical barrier. This accuracy improvement in turn facilitates more efficient HVAC system operations. Improved barrier description accuracy also beneficially conserves computational resources (processor cycles, memory, network bandwidth, electric power) by reducing resource usage on simulations that compute results using inaccurate barrier property descriptions. Also, the WSIBP functionality provides helpful supplementation or validation of barrier descriptions which are obtained from other approaches, such as building categorization, inference from architectural or construction documents, or inspection-by-a-human, when the other approaches are used. The WSIBP functionality also provides a substitute approach to obtain barrier data, which allows the other approaches (and their attendant disadvantages) to be avoided.

In some WSIBP embodiments, the barrier property value is associated with a barrier, and utilizing the barrier property value includes at least one of: adding a digital representation of the barrier to a digital representation of the building; or modifying a digital representation of the barrier in a digital representation of the building.

This WSIBP functionality has a technical benefit of increasing the accuracy of barrier property descriptions in a model, relative to actual physical properties of a corresponding physical barrier. In particular, in some scenarios the digital representation of the barrier is added because the previous digital representation of the building lacked any description of the barrier. This occurs, for example, when a wall is added to a building and the model of the building lacked the wall. In some scenarios, the model includes the wall, but a later significant physical change to the wall is not reflected in the model until after the WSIBP functionality modifies the digital representation of the wall, e.g., a door or a window is added or removed in the physical wall, or a layer of material (e.g., plaster or sheetrock or brick) is added or removed in the physical wall. Moving a wall is treated in some scenarios as removing the wall and adding a new wall with the same or similar material and thickness.

In some WSIBP embodiments, the method computes multiple barrier property values, and the method includes tuning the computational simulation by reducing a distance between a sensed thermal value and a sequence of simulated thermal values. The simulated thermal values are produced by the computational simulation from at least respective ones of the multiple barrier property values.

This WSIBP functionality has a technical benefit of increasing the accuracy of barrier property descriptions in a model, relative to actual physical properties of a corresponding physical barrier.

Notably, the simulation data flow and mechanisms in an embodiment are not limited to temperatures, but also include RF signal strengths, barrier material values, and barrier thickness values. By contrast, one temperatures-only approach would compare simulated temperatures to sensed temperatures and then update the weights or biases in a machine learning model of the simulation, without altering barrier material or barrier thickness (if those barrier values are even present in the simulation). Some temperatures-only simulations describe walls primarily or solely in terms of thermal characteristics, without any explicit values for wall material or wall thickness as such.

By contrast, this WSIBP functionality uses RF signal strength to infer barrier property(ies), which the simulation utilizes to more accurately predict temperatures computed from at least the barrier property(ies). Then those predictions are compared to actual sensed temperatures. That is in these example embodiments, a flow is from RF signal strength data, to values for barrier material or thickness or both which correspond to the RF signal strength data, to thermal characteristics of a barrier having that material and thickness, to simulation of temperatures based on those thermal characteristics, and then to comparison of the simulated temperatures against sensed temperatures. The values for barrier material or thickness or both that (a) match a barrier with the sensed RF signal strength within a defined tolerance, and (b) lead to the best match between simulated and actual (sensed) temperatures, are the barrier property values selected to optimally tune the simulation, because they reduce the distance between sensed thermal values and simulated thermal values.

This WSIBP functionality allows use of a machine learning (ML) model whose features would include barrier property value(s), but does not require use of any machine learning model. Other thermal flow simulation mechanisms that rely on barrier property value(s) will also benefit from increased accuracy of those value(s), including in particular other non-ML artificial intelligence models, statistical models used to understand relationships between variables or draw inferences, numerical models using finite difference or finite element techniques, or analytical models using human-defined rules, equations, and assumptions. Improving the accuracy of barrier property value(s) based on RF signal strength improves the accuracy of the description of the physical barrier, which in turn allows more accurate simulations of the barrier's thermal characteristics.

These and other advantages and benefits will be apparent to one of skill from the teachings provided herein.

### Operating Environments and Enhanced Systems

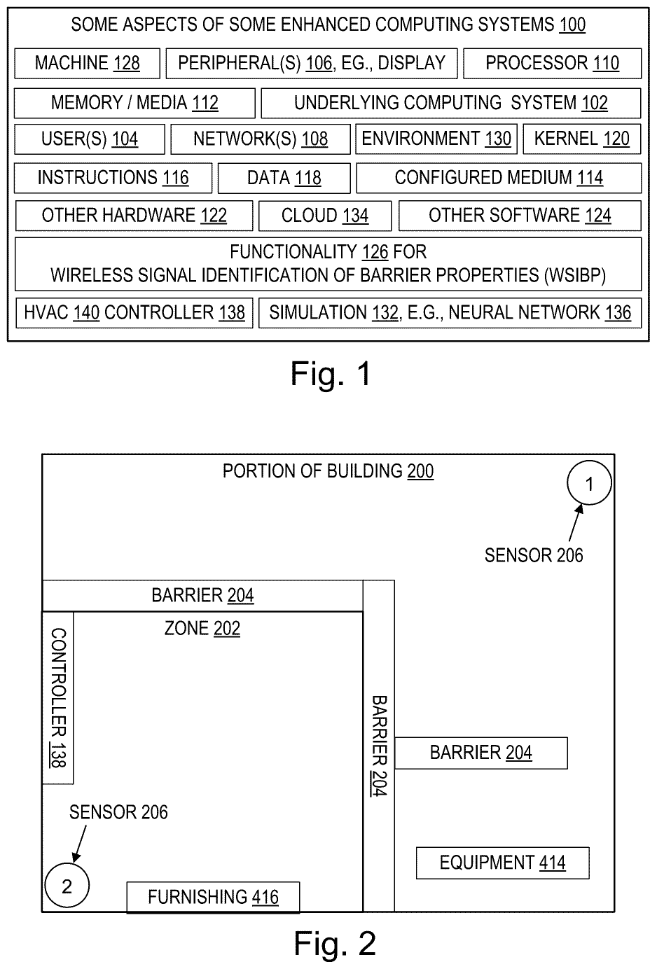

With reference to FIG. 1, an operating environment 130 for an example embodiment includes at least one computer system 102. The computer system 102 may be a multiprocessor computer system, or not. An operating environment may include one or more electrically-powered machines 128 in a given computer system, which may be clustered, client-server networked, and/or peer-to-peer networked within a cloud 134. An individual machine 128 which includes a processor 110 and a digital memory 112 is a computer system 102, and a network or other non-empty cooperating group of such machines 102 is also a computer system 102. A given computer system 102 may be configured for end-users, e.g., with a kernel 120, applications 124, and other software 124, for administrators, as a server, as an HVAC 140 controller 138, as an HVAC simulator 132, as a distributed processing node, and/or in other ways.

Human users 104 sometimes interact with a computer system 102 user interface by using displays 106, keyboards 106, and other peripherals 106, via typed text, touch, voice, movement, computer vision, gestures, and/or other forms of I/O (input/output).

In some embodiments, other computer systems not shown in FIG. 1 interact in technological ways with the computer system 102 or with another system embodiment using one or more connections to a cloud 134 and/or other network 108 via network interface equipment 122, for example.

Each computer system 102 includes at least one processor 110. The computer system 102, like other suitable systems, also includes one or more computer-readable storage media 112, also referred to as computer-readable storage devices 112, which in some embodiments are removable media 114.

Storage media 112 occurs in different physical types. Some examples of storage media 112 are volatile memory, nonvolatile memory, fixed in place media, removable media, magnetic media, optical media, solid-state media, and other types of physical durable storage media (as opposed to merely a propagated signal or mere energy). In particular, in some embodiments a configured storage medium 114 such as a portable (i.e., external) hard drive, CD, DVD, memory stick, or other removable nonvolatile memory medium becomes functionally a technological part of the computer system 102 when inserted or otherwise installed, making its content accessible for interaction with and use by processor 110. The removable configured storage medium 114 is an example of a computer-readable storage medium 112. Some other examples of computer-readable storage media 112 include built-in RAM, ROM, hard disks (solid state or magnetic or optical), and other memory storage devices which are not readily removable by users 104. For compliance with current United States patent requirements, neither a computer-readable medium nor a computer-readable storage medium nor a computer-readable memory nor a computer-readable storage device is a signal per se or mere energy under any claim pending or granted in the United States.

A storage device 114 is sometimes configured with binary instructions 116 that are executable by a processor 110; “executable” is used in a broad sense herein to include machine code, interpretable code, and/or code that runs on a virtual machine, for example. The storage medium 114 is also configured with data 118 which is created, modified, referenced, and/or otherwise used for technical effect by execution of the instructions 116. The instructions 116 and the data 118 configure the memory or other storage medium 114 in which they reside; when that memory or other computer readable storage medium is a functional part of a given computer system, the instructions 116 and data 118 also configure that computer system.

Although an embodiment may include software instructions 116 executed by one or more processors 110 in a computing device (e.g., general purpose computer, server, or cluster), such description is not meant to exhaust all possible embodiments. Embodiments do not necessarily include any software, and in some embodiments the only software is firmware. Alternatively, or in addition to a software implementation, technical functionality can be performed, in some examples, by one or more hardware logic components. For example, and without excluding other implementations, some embodiments include one of more of: chiplets, hardware logic components 110, 122 such as Field-Programmable Gate Arrays (FPGAs), Application-Specific Integrated Circuits (ASICs), Application-Specific Standard Products (ASSPs), System-on-a-Chip (SoC) components, Complex Programmable Logic Devices (CPLDs), and similar components. In some embodiments, components are grouped into interacting functional modules based on their inputs, outputs, or their technical effects, for example.

In addition to processors 110 (e.g., CPUs, ALUs, FPUs, TPUs, GPUs, and/or quantum processors), memory/storage media 112, peripherals 106, and displays 106, some operating environments also include other hardware 122, such as batteries, buses, power supplies, wired and wireless network interface cards, sensors, transmitters, receivers, or HVAC equipment 138, for instance. The nouns “screen” and “display” are used interchangeably herein.

In some embodiments or operating environments, an enhanced system 100 includes multiple computers and/or other hardware 122 connected by a wired and/or wireless network 108. Networking interface equipment 122 can provide access to networks 108, using network components such as a packet-switched network interface card, a wireless transceiver, or a telephone network interface, for example, which are present in some computer systems. In some, virtualizations of networking interface equipment and other network components such as switches or routers or firewalls are also present, e.g., in a software-defined network or a sandboxed computing environment or another secure computing environment. In some embodiments or operating environments, one or more computers are partially or fully “air gapped” by reason of being disconnected from, or only intermittently connected to, another networked device or a remote cloud. Some examples also communicate technical data or technical instructions or both through direct memory access, removable or non-removable volatile or nonvolatile storage media, or other information storage-retrieval and/or transmission approaches.

In some embodiments, the enhanced system 100 is networked through an interface 122. In some, an interface 122 includes hardware such as network interface cards, software such as network stacks, APIs, or sockets, combination items such as network connections, or a combination thereof.

Some embodiments include a computing system 100 which is equipped, structured, or otherwise configured to utilize or provide WSIBP functionality 126. The system 100 includes an underlying computer system 102 which includes a digital memory 112, and a processor 110. The processor is in operable communication with the digital memory. A digital memory is also referred to as a memory 112. The word “digital” is used to emphasize that the memory 112 is part of a computing system 102, not a human person's memory, but with that understood not every reference to a digital memory herein recites “digital”. The memory 112 is configured by instructions and data residing within it which support or provide WSIBP functionality, e.g., the instructions upon execution by the processor perform a WSIBP method 1000 described herein. FIGS. 1-6 and 11 illustrate aspects of such enhanced systems 100.

FIG. 2 shows a portion of a building 200. FIG. 2 does double duty in this disclosure, in that the building and other items shown are either physical real-world items, on the one hand, or simulation models of physical real-world items, on the other hand. One of skill will understand from context which is being discussed (or that both are being discussed) from indications such as the use of terms like “physical”, “real-world”, “actual”, “tangible”, “sensed”, on the one hand, or terms like “simulation”, “simulated”, “model”, “digital”, “computational”, “compute”, “calculated”, “execute”, or terms involving mathematical operations, on the other hand.

Some items cross over, e.g., sensor data is collected from physical sensors 206 but used in simulations 132. Zones 202 are defined, e.g., by barriers 204, both in the real world and in a model 132. A given barrier 204 has properties 502 such as the material(s) 402 that compose the barrier, the barrier's thickness 404, the barrier's temperature, the barrier's RF signal attenuation at one or more RF frequencies or frequency ranges, the barrier's surface area, the barrier's layer mass, the barrier's thermal capacitance, the barrier's layer specific heat capacity, and others.

Any object or condition that impacts RF signals and thermal flow, or potentially impacts them but is actually neutral, can be treated in a simulation as a barrier. Examples of RF signal impact include boosting signal strength (i.e., negative attenuation) or reducing signal strength (which is the effect in most circumstances).

Some barrier examples include HVAC controllers 138, fans, air conditioning units, pumps, heaters, heat exchangers, chillers, condensers, boilers, ducts, and other HVAC equipment 414, which exist both in the real world and in a model 132. In some simulations, barriers also include furnishings 416 such as shelves, wardrobes, metal furniture, heavy or thick furniture as determined by specified thresholds, aquariums, water tanks, and other items placed or installed in the building, which reduce RF signal strength; these items likewise exist both in the real world and in a model 132.

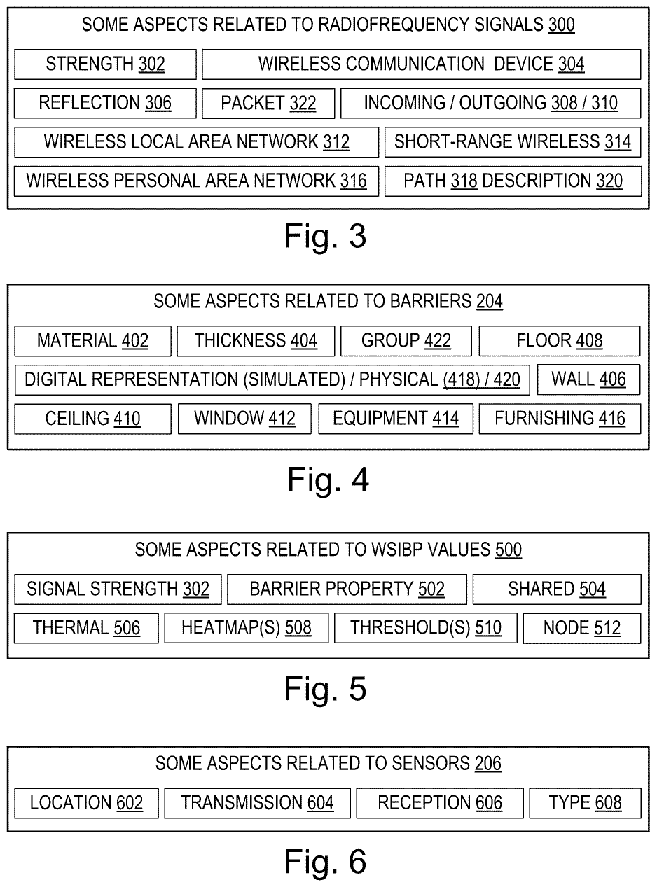

Items shown in FIGS. 3 through 6 and 11 are discussed at various points in the present disclosure. They have meanings understood in the art by one of skill, in some instances modified by discussion herein. For instance: wireless communication devices 304 include sensors 206; material 402 and thickness 404 are examples of barrier 204 properties 502; a group 422 includes two or more barriers 204; and sensor type 608 refers to the type of data collectable from a sensor 206 such as one or more of: RF signal strength data, RF signal packet 322 data, humidity, or thermal data 506. Some sensors 206 also provide operational data such as one or more of: battery level, location 602 (e.g., in a network, relative to barrier(s), or as GPS coordinates) physical sensors are located in or within sensing range of a physical building), or sensor state data (e.g., incoming signal 308/listening mode or outgoing signal 310/broadcast mode).

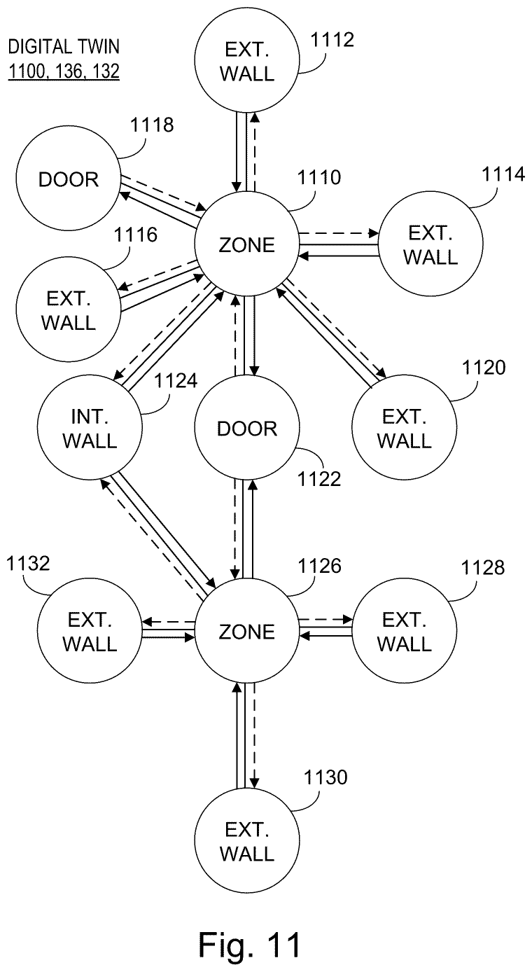

In some embodiments, a simulation 132 includes a heterogenous neural network 136, also illustrated in FIG. 11. This neural network has activation functions in nodes 512 that perform separate calculations to determine weight values that exit the node. These calculations include thermodynamic calculations that determine how thermal state flows through the node. States are characterized as weights entering and exiting nodes. In operation, this example neural network includes inputs, outputs, and hidden layers connected by edges which have weights associated with them. The neural net sums the weights of all the incoming edges, applies a bias, and then uses an activation function to introduce non-linear effects, which basically squash or expand the weigh/bias value into a useful range, sometimes determining whether the node will fire or not. This new value then becomes a weight used for connections to the next hidden layer of the network. The activation function does not necessarily do separate calculations, depending on the node, and does not necessarily have physics equations associated with it.

In some heterogenous neural networks, fundamentals of physics are utilized to model single barriers 204 or pieces of equipment 414, 138 on a one-to-one basis with neural net nodes, alone or in sets. When multiple components are linked to each other in a schematic diagram, a neural net is created that models these components as nodes. The values between the objects flow between the nodes as weights of connected edges. In some scenarios, these neural nets model not only the real complexities of systems but also their emergent behavior and the system semantics.

In some embodiments, the individual neural network 136 nodes 512 represent physical representations of chunks 204 of building material within a structure, equipment 414, etc. These individual nodes hold parameter values 500 that help define the physical building's digital representation 418, sometimes referred to as the building's digital twin 418. As such, when the neural net is run, the parameters helping define the physical representation can be tweaked 802 to more accurately represent the physical characteristics. This has the effect of pre-training 1034 the model 132, 136 with a qualitative set of guarantees, as the physics equations that describe objects being modeled are true, which conserves computational resources by avoiding finding training sets and using huge amounts of computational resources to run the training sets through the models to train them. A model 132 does not need to be trained with information about the real world that is already embedded in the model as barrier property values. With objects connected in the neural net as they are connected in the real world, emergent behavior arises in the model that maps effectively and efficiently to the real world, e.g., for operational control 138 of HVAC equipment. This model behavior that is uncovered is sometimes too computationally complex to determine otherwise, e.g., by an analytic approach alone. Further, in these examples the nodes 512 represent actual objects in the real world, not black boxes. The behavior of the nodes themselves can be examined to determine behavior of the object, and can also be used to refine understanding of the object's behavior.

In one example, an outside node in the heterogenous network 136 is associated with a time heat curve T. The curve value at time t(−n) is injected into one or more outside nodes 512. This temperature is propagated through the building 200 digital representation, e.g., through the represented layers (brick, insulation, drywall, etc.) by modifying values 500 of the nodes of the simulation neural net using physics representation. The outside of the building (say, brick), has its temperature 506 modified by the outside node and known aspects of how heat transfers through brick as found in the brick node. The brick then heats up the next layer, perhaps insulation. This continues throughout the building until an inside node is reached, e.g., a node that represents the space 202 inside a room. At inside nodes, other functions are sometimes applied, e.g., to represent lighting and people (warmth) within the zone of the node. State information continues to propagate until another outside layer is reached, with individual node parameter values representing the heating present in the building at time T0. In some embodiments, each outer surface has its own time temperature curve. In some embodiments a structure is deconstructed into smaller subsystems, or zones 202, and rather than propagating temperature through the entire structure, only a portion of the structure is affected by a given input.

FIGS. 1-6 and 11 do not individually or collectively or in any subset fully define a comprehensive summary of all aspects of enhanced systems 100 or all aspects of WSIBP functionality 126. Nor is any figure of FIGS. 1-6 and 11 or any group of figures of FIGS. 1-6 and 11 by itself a comprehensive summary of all aspects of an environment 130 or another context of an enhanced system 100.

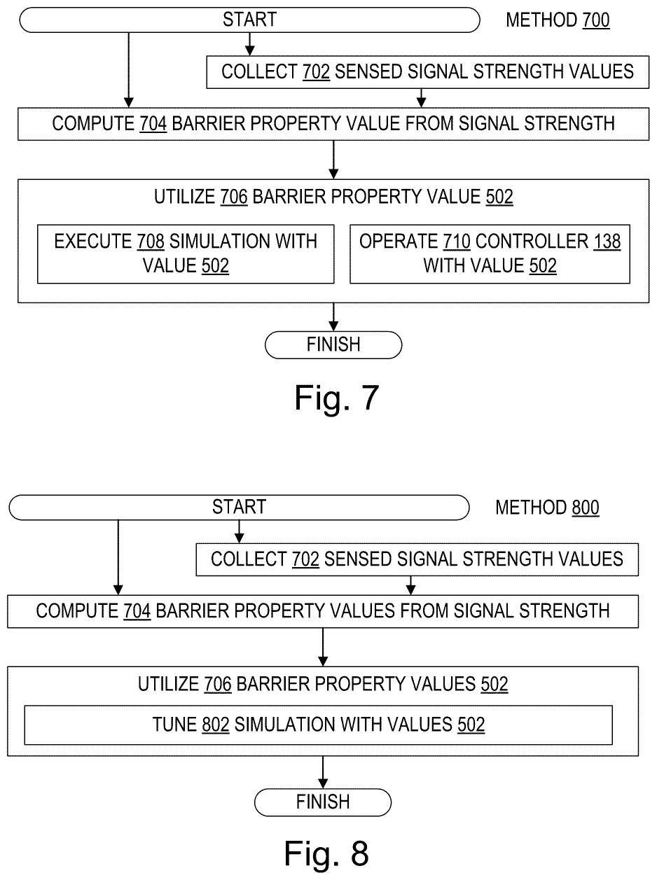

The other figures are also relevant to enhanced systems 100. FIGS. 7 to 10 are flowcharts which illustrate some methods of WSIBP functionality 126 operation in some systems 100.

One of skill will appreciate that the foregoing aspects and other aspects presented herein under “Operating Environments” form part of some example embodiments, but are not required in every embodiment. This document's headings are not intended to provide a strict classification of features into embodiment and non-embodiment feature sets.

In any later application that claims priority to the current application, reference numerals may be added to designate items disclosed in the current application. Such items may include, e.g., software, hardware, steps, processes, systems, functionalities, mechanisms, connections, devices, data structures, kinds of data, settings, parameters, components, computational resources, workflows, or algorithm implementations, or other items in an environment 130, which are disclosed herein but not associated with a particular reference numeral herein. Corresponding drawings may also be added.

### Processes (a.k.a. Methods)

Processes (which are also referred to as “methods” in the legal sense of that word) are illustrated in various ways herein, both in text and in drawing figures. FIGS. 7 to 10 each illustrate a family of methods 700, 800, 900, and 1000 respectively, which are performed or assisted by some enhanced systems, such as some systems 100 or another functionality enhanced system as taught herein. Method families 700, 800, and 900 are each a proper subset of method family 1000. Moreover, activities identified in FIGS. 1 to 6 or FIG. 11 as explicit or implicit method steps are likewise incorporated into method 1000. Also, steps that are not expressly tied herein to a particular reference number are not thereby excluded from method 1000. These diagrams and flowcharts are merely examples; as noted elsewhere, any operable combination of steps that are disclosed herein may be part of a given embodiment when called out in a claim.

Technical processes shown in the Figures or otherwise disclosed will be performed automatically, e.g., by an enhanced system 100, unless otherwise indicated. Related non-claimed processes may also be performed in part automatically and in part manually to the extent action by a human person is implicated, e.g., in some situations a human 104 types text into a system 100. Regardless, no process contemplated as an embodiment herein is entirely manual or purely mental; none of the claimed processes can be performed solely in a human mind or on paper. Any claim interpretation to the contrary is squarely at odds with the present disclosure.

In a given embodiment zero or more illustrated steps of a process may be repeated, perhaps with different parameters or data to operate on. Steps in an embodiment may also be done in a different order than the top-to-bottom order that is laid out in FIG. 10. In the event of any alleged inconsistency, lack of clarity, or excessive breadth due to an interpretation of FIG. 10, the content of this disclosure shall prevail over that negative interpretation of FIG. 10.

Arrows in process or data flow figures indicate allowable flows; arrows pointing in more than one direction thus indicate that flow may proceed in more than one direction. Steps may be performed serially, in a partially overlapping manner, or fully in parallel within a given flow. In particular, the order in which flowchart 1000 action items are traversed to indicate the steps performed during a process may vary from one performance instance of the process to another performance instance of the process. The flowchart traversal order may also vary from one process embodiment to another process embodiment. Steps may also be omitted, combined, renamed, regrouped, be performed on one or more machines, or otherwise depart from the illustrated flow, provided that the process performed is operable and conforms to at least one claim of an application or patent that includes or claims priority to the present disclosure. To the extent that a person of skill considers a given sequence S of steps which is consistent with FIG. 10 to be non-operable, the sequence S is not within the scope of any claim. Any assertion otherwise is contrary to the present disclosure.

Some embodiments provide or utilize a method 1000 which is performed by a computing system. The method includes: collecting 702 two sensed signal strength values of a radiofrequency signal (e.g., via an API); computing 704 a barrier property 502 value 500 from at least the two sensed signal strength 302 values 500 (e.g., by lookup into a table or a dictionary which correlates signal strength values with barrier property values), the barrier property value representing a barrier material 402 or a barrier thickness 404; and utilizing 706 the barrier property value in at least one of: executing 708 a computational simulation of heat transfer which employs 1032 a digital representation 418 of a building 200, or operating 710 a heating control mechanism 138 which controls heating of a physical building 200, 420.

In some embodiments, the barrier property value 500 is associated with a barrier 204, and utilizing 706 the barrier property value includes at least one of: adding 1002 a digital representation of the barrier to the digital representation of the building; or modifying 1004 a digital representation of the barrier in the digital representation of the building.

In some embodiments, the barrier property value 500 represents a property value 502 of a barrier 204, the method includes ascertaining 1006 that the barrier belongs to a group 422 of barriers which share a shared 504 property value, and computing 704 the barrier property value includes: in response to the ascertaining, conforming 1008 the barrier property value to the shared property value.

For example, in one embodiment the method ascertains 1006 that a wall 204 belongs to an exterior wall group 422, and in response conforms the wall's material 402 value 502, 500 to “brick layer, insulation layer, concrete block layer, cladding layer”. As another example, in one embodiment the method ascertains 1006 that a zone wall 204 belongs to an interior partition wall group 422, and in response conforms the wall's thickness 404 to 4 inches (100 mm).

In some embodiments, the two sensed signal strength values are both collected 702 from one sensor 206, and one of the two sensed signal strength values corresponds to a reflection 306 of the radiofrequency signal. This assists in identifying barrier materials 402 because some materials, e.g., metal in windows or mirrors or other metallic objects, are more highly reflective of RF signals than other materials, e.g., concrete and brick, which are more absorbent and less reflective. Signal strength loss can be direction dependent due to reflectance.

In some embodiments, the two sensed signal strength values are collected from at least two sensors, one of the two sensed signal strength values corresponds to the radiofrequency signal prior to a transmission 604 of the radiofrequency signal through the barrier, and the other corresponds to the radiofrequency signal after the transmission of the radiofrequency signal through the barrier. This assists in identifying barrier materials 402 because different materials have different RF signal strength attenuation impacts, which are documented in some embodiments in tables, dictionaries, lists, trees, or other data structures that correlate materials with attenuations.

Some embodiments provide or utilize a method 1000 which is performed by a computing system. The method includes: collecting 702 two sensed signal strength values of a radiofrequency signal; computing 704 at least two different barrier property values from at least the two sensed signal strength values, each barrier property value representing a respective barrier material of a barrier or a respective barrier thickness of the barrier; and utilizing 706 the at least two different barrier property values in tuning 802 a simulation 132.

In some embodiments, the method includes getting 1010 a simulated thermal value 506, 500 of a zone 202 which adjoins the barrier, the simulated thermal value produced by the simulation; and collecting 1012 a sensed thermal value 506, 500 of the zone, the sensed thermal value produced by a sensor physically located in the zone; and tuning the simulation includes selecting 1014 and installing 1016 in the simulation whichever of the at least two different barrier property values produces 1018, via the simulation, an updated simulated thermal value of the zone which is closest to the sensed thermal value of the zone.

In these example embodiments, a data and control flow of the embodiment is from RF signal strengths to compute at least one barrier property, to identify a thermal characteristic of the barrier based on at least the barrier property, to calculate a prediction of the thermal impact of the barrier, which is then compared to sensed thermal impact, and the barrier property value is selected or replaced according to how well the predicted thermal impact matches the actual thermal impact. In other words, RF signal strength data is leveraged to improve the accuracy of barrier thermal representations in thermal flow simulations.

In some embodiments, computing 704 at least two different barrier property values includes tracing 1020 a packet 322 of the radiofrequency signal, e.g., using the packet's ID, to create 1022 a path 318 description 320 (e.g., list of visited device identifiers) that includes at least two sensors 206 which are located at respective physical locations 602 at least one meter apart.

For example, in one scenario a signal follows a path 318 from a sensor A where it has signal strength A, through a barrier X, to a sensor B where it has signal strength B. The attenuation between signal strength A and signal strength B is attributed to barrier X, and used to compute 704 barrier X property value(s). In another scenario a signal follows a path 318 from a sensor A where it has signal strength A, through a barrier X and a barrier Y, to a sensor B where it has signal strength B. The attenuation between signal strength A and signal strength B is attributed to barrier X and barrier Y, and used to compute 704 barrier X and barrier Y property value(s), either in combination or separately, or both.

In another example, given two sensors A and B on two sides of a barrier, the method sets sensor A into receiving mode and sensor B into transmission mode, so that B broadcasts signals and A receives them as they pass through the barrier. Some methods also do the opposite where B transmits 604 signals and A receives 606 the signals. In some scenarios, only one transmitter and one receiver are used, without any mode changes. However, depending on the topology of the barriers, some methods exercise more control over the sensors to put them into transmitting or receiving modes in order to cover different cases, e.g., where a wall is positioned such that switching sensor modes is beneficial by providing a receiver on one side of the wall and a transmitter on the other side of the wall.

Switching modes also allows a system to cover more walls. Assume there are three walls with three sensors A, B, and C positioned as “A∥B∥C”. If a system has control over the sensor modes, it can use A as receiver and B as transmitter to measure for the left wall. Then it can use B as transmitter and C as receiver to measure right wall. But it could also use C as transmitter and A as receiver to see how the signal travels through multiple walls.

In some embodiments, tracing 1020 includes a version of ray-tracing, which selects a point in the building and assumes a sensor is located at that point so only a single sensor is needed. Then, from that point, signals are sent in different angles. Depending on the capabilities of the sensor's antenna, frequency, etc., these signals could be sent in all 360 degrees around the point. Then, for each of those signals, the tracing system sees if they hit barriers on the way, and based on the digital twin, measures how much of it would be reflected and how much would pass through the material. These are the first level of reflections. Some systems then do the same thing for the part of the signal that is reflected, again, and that would be the second level of reflections. Some systems can continue as long as something is reflected, but in practice systems are likely to do at most three levels of reflections for each signal starting from the sensor, because adding each reflection adds to the complexity, and the accuracy of the heatmap produced as the output reaches a point of diminishing returns. Some systems perform ray-tracing for all the available sensors, separately, producing a signal strength heatmap (or radio map) per sensor.

When a system has real measurements at some points in the building, the system can use those measurements and compare them to their peers in the simulated signal strength heatmaps and use their difference as an error to tune the parameters used to produce heatmaps in the first place. Some embodiments continue this process of tuning the parameters and repeating the calculation of the heatmap through ray-tracing, until they reach a point where the heatmap is within a defined tolerance of the real measurements from the real physical sensors in the building.

Instead of running ray-tracing, some systems do heat transfer simulations to get the heatmaps. Then they compare the values of the heatmap with the actual temperature sensor measurements and use the difference as an error to tune the material properties (parameters) used in the simulation. Some do both ray-tracing and heat transfer simulations to produce heatmaps.

In some embodiments, tuning 802 the simulation includes: producing 1024 a simulation thermal heatmap 508 of thermal values 506, 500, and comparing 1026 a sensed thermal value to the simulation thermal heatmap.

In some scenarios, assuming the simulation is otherwise tuned, e.g., as to the physics equations and the thermal characteristics of respective materials which it employs, the results of the comparison 1026 indicate the accuracy of the barrier properties from which the simulation predicted the thermal heatmap values. Therefore, barrier properties that lead to a better match between a sensed thermal value and the simulation thermal heatmap are installed in, or maintained in, the simulation.

In some embodiments, tuning 802 the simulation includes: producing 1024 a simulation signal strength heatmap of signal strength values 302, 500, and comparing 1026 to the simulation signal strength heatmap at least one of: one of the two sensed signal strength values, or another sensed signal strength value (e.g., using Received Signal Strength Indicator measurements).

In some scenarios, when the simulation signal strength heatmap is tuned to match the sensed signal strength values, the simulation signal strength heatmap is available for use within the simulation to supplement or replace sensed signal strength values. This can speed simulation execution 708, because use of internal values 500 is generally faster than performing I/O to obtain values from sensors.

In some embodiments, tuning 802 the simulation includes: computationally determining 1028 that a difference between respective ones of the two sensed signal strength values is greater than a predetermined upper threshold 510, and in response to the determining, updating 1030 the simulation by an updated barrier material 402 selection instead of updating 1030 the simulation by an updated barrier thickness 404 selection.

In some scenarios, a large attenuation in signal strength indicates a barrier made of highly absorbent material, rather than a very thick barrier of a less absorbent material. For example, a 12.7 mm thick drywall panel or a 6 mm thick plywood sheet each has an RF signal attenuation of less than 1 dB at 5 GHz, whereas a brick or masonry block of defined respective thicknesses (at least 110 mm) each has an attenuation of 15 dB at 5 GHz. If an attenuation due to a barrier is with a defined tolerance of 15 dB, e.g., between 13.5 dB and 16.5 dB, then the barrier is much more likely to be a brick or masonry block wall than it is to be ten or twenty layers of drywall or plywood. Accordingly, instead of keeping drywall or plywood as the material and increasing the thickness value 500, the method 1000 changes the material value 500 to brick or masonry block.

In some embodiments, tuning 802 the simulation includes: determining 1028 that a difference between respective ones of the two sensed signal strength values is less than a predetermined lower threshold 510, and in response to the determining, updating 1030 the simulation by an updated barrier thickness 404 selection instead of updating 1030 the simulation by an updated barrier material 402 selection.

In some scenarios, a small attenuation in signal strength indicates the barrier thickness is slightly mis-approximated. For example, a 12.7 mm thick drywall panel or a 6 mm thick plywood sheet each has an RF signal attenuation of less than 1 dB at 5 GHz. If an attenuation due to a barrier is within a defined tolerance for 1 dB, e.g., between 1.5 dB and 2.5 dB, then the barrier is more likely to be two layers of drywall or plywood than it is to be a single layer of such material, and the barrier is very unlikely to be made of a different more absorbent material such as brick or masonry block. Accordingly, instead of changing the material value 500 to brick or masonry block, the method keeps drywall or plywood as the material and increases the thickness value 500.

In some embodiments, tuning 802 the simulation includes: determining 1028 that a difference between respective ones of the two sensed signal strength values is greater than a predetermined upper threshold 510, and in response to the determining, replacing 1030 a first barrier thickness selection by a second barrier thickness selection which is at least ten times the first barrier thickness selection.

In some scenarios, barrier representations are initialized with nominal or default thickness values such as 0, or 0.1 mm. This may occur, in particular, when the barrier is a placeholder in the simulation, and confirmation is not yet obtained whether the physical building contains a physical barrier corresponding to the placeholder simulated barrier, or due to floor planning error (e.g., assuming thickness of 0, which is a missing wall, or a missing layer in the wall). When sensed signal strength values indicate a significant RF signal attenuation, e.g., above a threshold of 0.9 dB, the nominal or default thickness value such as 0.0 mm or 0.1 mm is replaced by a thickness corresponding to the thinnest material typically used, e.g., ¼ inch (6.35 mm) for drywall. In a similar example scenario, a wall with a thickness of 10 inches is estimated initially to be 0.1 inch thick.

In some embodiments, the two sensed signal strength values include an incoming 308 sensed signal strength value and an outgoing 310 sensed signal strength value, the incoming sensed signal strength value corresponding to the radiofrequency signal incoming to a wireless communication device, e.g., a sensor 206, and the outgoing sensed signal strength value corresponding to the radiofrequency signal outgoing from the wireless communication device. That is, in some scenarios the same device provides both of the sensed signals which are used to measure RF signal strength attenuation.

In some embodiments, the radiofrequency signal 300 includes at least one of: a wireless network 304 signal, a wireless local area network 312 signal, a short-range wireless 314 communication signal, or a wireless personal area network 316 signal. Some examples of short-range RF signals include Bluetooth® or BLE (Bluetooth Low energy) signals (mark of Bluetooth SIG, Inc.). Some examples of long-range RF signals include, and Wi-Fi® signals (mark of the Wi-Fi Alliance).

In some embodiments, the barrier 204 includes a wall 406, a floor 408, a ceiling 410, a window 412, a machine 128, or a furnishing 416.

### Configured Storage Media

Some embodiments include a configured computer-readable storage medium 112. Some examples of storage medium 112 include disks (magnetic, optical, or otherwise), RAM (random access memory), EEPROMs (electronically erasable read-only memories) or other ROMs (read-only memories), and other configurable memory, including in particular computer-readable storage media (which are not mere propagated signals). In some embodiments, the storage medium which is configured is in particular a removable storage medium 114 such as a CD, DVD, or flash memory. A general-purpose memory, which is removable or not, and is volatile or not, depending on the embodiment, can be configured in the embodiment using items in the form of data 118 and instructions 116, read from a removable storage medium 114 and/or another source such as a network connection, to form a configured storage medium. The foregoing examples are not necessarily mutually exclusive of one another.

The configured storage medium 112 is capable of causing a computer system 100 to perform technical process steps for providing or utilizing WSIBP functionality 126 as disclosed herein. The Figures thus help illustrate configured storage media embodiments and process (a.k.a. method) embodiments, as well as system and process embodiments. In particular, any of the method steps illustrated in FIGS. 7 to 10, or otherwise taught herein, may be used to help configure a storage medium to form a configured storage medium embodiment.

Some embodiments use or provide a computer-readable storage device (a.k.a. medium) 112, 114 configured with data 118 and instructions 116 which upon execution by a processor 110 cause a computing system 100 to perform a method 1000. The method includes: computing 704 a barrier property value from at least two sensed signal strength values, the barrier property value representing a barrier material or a barrier thickness; and utilizing 706 the barrier property value in at least one of: executing 708 a computational simulation of heat transfer which employs a digital representation of a building, tuning 802 the computational simulation, or operating 710 (e.g., by command issuance or control signal transmission) a heating control mechanism 138 which controls heating of a physical building.

In some embodiments, the method computes 704 multiple barrier property values, the method includes tuning 802 the computational simulation by reducing 1018 a distance between a sensed thermal value and a sequence of simulated thermal values, the simulated thermal values being produced 1024 by the computational simulation from at least respective ones of the multiple barrier property values.

In some embodiments, the method comprises tuning the computational simulation, and the tuning includes: determining 1028 that a difference between respective ones of the two sensed signal strength values is greater than a predetermined upper threshold 510, and in response to the determining, replacing 1030 a first barrier thickness selection by a second barrier thickness selection which is at least five times the first barrier thickness selection.

In some embodiments, the barrier 204 includes a floor or a ceiling or both. The barrier may include multiple layers or materials, e.g., radiant heating components.

In some embodiments, the barrier 204 includes a machine or another piece of equipment located on a floor.

### Additional Observations

Wireless signals such as Wi-Fi signals are highly affected by their environment. Therefore, given a wireless network access point in a room, when the signals reach the wall, some would pass through it and some would be reflected back, go through some other material, and so on. The amount of signal penetration and reflection depends on the materials'properties. Assuming some initial material properties, a system 100 can estimate how the signal strength would be affected when it passes a certain material. Then, given the actual signal strength on the other side of the wall, the system can use the difference to tune the initial guess about the material properties.

Continuing this example, assume access point AP1 is in the room and access point AP2 is outside the room. AP1 and AP2 can listen for each other's signals and know the signals'strengths as they pass through the walls. Similarly, suppose a model initially assumes the walls are made of 5-inch concrete. Using the physics signal propagation and reflection formulas, the system 100 can calculate how much the signal strengths of AP1 would be if they go through a concrete wall with 5-inch thickness after traveling a certain distance. Using AP2, the system can collect the real value of AP1's signals when they go through the wall. Therefore, the system can refine the approximation of the material's properties that are injected into physics formulas, and determine that for instance, the thickness of the wall was in fact 4.5 and not 5.5.

FIG. 11 illustrates an example digital twin 1100 for construction by or use in various embodiments. The digital twin 700 corresponds, for example, to an omnidirectional, heterogenous, ontologically-labeled neural network digital twin 136 or other digital twin model 136, in some embodiments. As shown, the digital twin 1100 includes a number of nodes 512 labeled 1112 through 1132 connected to each other via edges. As such, the digital twin 1100 is arranged as a graph, such as a neural network 136 graph, in some embodiments. In various alternative embodiments, other arrangements are used. Further, while the digital twin 1100 resides in storage as a graph type data structure in some embodiments, various alternative data structures are also used for the storage of a digital twin 1100 as described herein. The nodes 1112 through 1132 correspond to various aspects of a building structure such as zones, walls, and doors. The edges between the nodes 1112 through 1132 represent relationships between the aspects represented by the nodes 1112 through 1132, such as adjacency for heat transfer.

As shown, the digital twin 1100 includes two nodes 1110, 1126 representing zones 202. A first zone node 1110 is connected to four exterior wall nodes 1112, 1114, 1116, 1120; two door nodes 1118, 1122; and an interior wall node 1124. A second zone node 1126 is connected to three exterior wall nodes 1128, 1130, 1132; a door node 1122; and an interior wall node 1124. The interior wall node 1124 and door node 1122 are connected to both zone nodes 1110, 1126, indicating that the corresponding structures divide the two zones. This digital twin 1100 thus corresponds to a two-room structure.

The example digital twin 1100 is, in some respects, a simplification. For example, in some embodiments digital twin 1100 includes additional nodes representing other aspects, such as additional zones, windows, ceilings, foundations, roofs, or external forces such as the weather or a forecast thereof. In various embodiments the digital twin 1100 encompasses alternative or additional systems, such as controllable systems of equipment (e.g., HVAC systems).

In some embodiments, the digital twin 1100 is a heterogenous neural network. Some neural networks are formed of multiple layers of neurons interconnected to each other, each starting with the same activation function. Through training, each neuron's activation function is weighted with learned coefficients such that, in concert, the neurons cooperate to perform a function. The example digital twin 1100, on the other hand, includes in some embodiments a set of activation functions (shown as solid arrows) that are, even before any training or learning, differentiated from each other, i.e., heterogenous. In various embodiments, the activation functions are assigned to the nodes 1110-1132 based on domain knowledge related to the system being modeled. For example, some activation functions include appropriate heat transfer functions for simulating the propagation of heat through a physical environment (such as a function describing the radiation of heat from or through a wall of particular material and dimensions to a zone of particular dimensions). As another example, some activation functions include functions for modeling the operation of an HVAC system at a mathematical level (e.g., modeling the flow of fluid through a hydronic heating system and the fluid's gathering and subsequent dissipation of heat energy). Such functions are sometimes referred to as “behaviors” assigned to the nodes 1110-1132. In some embodiments, each of the activation functions include multiple separate functions; such an implementation is useful when more than one aspect of a system is modeled from node-to-node. For example, in some cases each of the activation functions includes a first activation function for modeling heat propagation and a second activation function for modeling humidity propagation. In some embodiments, these diverse activation functions along a single edge are defined in opposite directions. For example, in some cases a heat propagation function is defined from node 1110 to node 1112, while a humidity propagation function is defined from node 1112 to node 1110. In some embodiments, the diversity of activation functions differs from edge to edge. For example, in some cases one activation function includes only a heat propagation function, another activation function includes only a humidity propagation function, and yet another activation function includes both a heat propagation function and a humidity propagation function.

In some embodiments, the digital twin 1100 is an omnidirectional neural network. Some neural networks are unidirectional, in that they include an input layer of neurons that activate one or more hidden layers of neurons, which then activate an output layer of neurons. In use, some neural networks use a feed-forward algorithm where information only flows from input to output, and not in any other direction. Even in deep neural networks, where other paths including cycles are sometimes used (as in a recurrent neural network), the paths through the neural network are defined and limited. The example digital twin 1100, on the other hand, in some embodiments includes activation functions along both directions of each edge: the previously discussed “forward” activation functions (shown as solid arrows) as well as a set of “backward” activation functions (shown as dashed arrows).

In some embodiments, at least some of the backward activation functions are defined in the same way as described for the forward activation functions, based on domain knowledge. For example, while physics-based functions are sometimes used to model heat transfer from a surface (e.g., a wall) to a fluid volume (e.g., an HVAC zone), similar physics-based functions are sometimes used to model heat transfer from the fluid volume to the surface. In some embodiments, some or all of the backward activation functions are derived using automatic differentiation techniques. Specifically, according to some embodiments, reverse mode automatic differentiation is used to compute the partial derivative of a forward activation function in the reverse direction. This partial derivative is then be used to traverse the graph in the opposite direction of that forward activation function. Thus, for example, while the forward activation function from node 1112 to node 1110 is defined based on domain knowledge and allows traversal (e.g., state propagation as part of a simulation) from node 1112 to node 1110 in linear space, the reverse activation function is defined as a partial derivative computed from that forward activation function and allows traversal from node 1110 to 1112 in the derivative space. In this manner, traversal from any one node to any other node is enabled. For example, the graph is traversable (e.g. state propagation is supported) from node 1114 to node 1116, first through a forward activation function, through node 1110, then through a backward activation function. By forming the digital twin as an omnidirectional neural network, its utility is greatly expanded; rather than being tuned for one particular task, it can be traversed in any direction to simulate different system behaviors of interest and can be employed beneficially to answer many different questions.

In some embodiments, the digital twin is an ontologically labeled neural network. In some neural networks, individual neurons do not represent anything in particular; they simply form the mathematical sequence of functions that will be used (after training) to answer a particular question. Further, while in deep neural networks, neurons are grouped together to provide higher functionality (e.g. in recurrent neural networks and convolutional neural networks), these groupings do not represent anything other than the specific functions they perform; i.e., they remain simply a sequence of operations to be performed.

The example digital twin 1100, on the other hand, in some embodiments ascribes meaning to each of the nodes 1110-1132 and edges therebetween by way of an ontology. For example, in some cases the ontology defines one or more concepts which are relevant to a particular system being modeled by the digital twin 1100 such that each node or connection can be labeled according to its meaning, purpose, or role in the system. In some embodiments, the ontology is specific to the application (e.g., including specific entries for each of the various HVAC equipment, sensors, and building structures to be modeled), while in others, the ontology is generalized in some respects. For example, rather than defining specific equipment, in some cases the ontology defines generalized “actors” (e.g., the ontology defines producer, consumer, transformer, and/or other actors for ascribing to nodes) that operate on “quanta” (e.g., the ontology defines fluid, thermal, mechanical, and/or other quanta for propagation through the model) passing through the system. Additional aspects of the ontology in some cases allow for definition of behaviors and properties for the actors and quanta that serve to account for the relevant specifics of the object or entity being modeled. For example, through the assignment of behaviors and properties, the functional difference between one “transport” actor and another “transport” actor is captured in some embodiments.

The above techniques, alone or in combination, enable a fully-featured and robust digital twin 1100, suitable for many purposes including system simulation and control path finding. The digital twin 1100 in some embodiments is computable and trainable like a neural network, is queryable like a database, is introspectable like a semantic graph, and/or is callable like an API.

As described above, in some embodiments the digital twin 1100 is traversable in any direction by application of activation functions along each edge. Thus, information can be propagated from input node(s) to output node(s). A difference in some embodiments is that the input and output nodes are specifically selected on the digital twin 1100, based on the question being asked, and sometimes differ from question to question. In some embodiments, the computation occurs iteratively over a sequence of timesteps to simulate over a period of time. For example, the digital twin 1100 and activation functions are set in some cases at a particular timestep (e.g., 1 minute), such that each propagation of state simulates the changes that occur over that period of time. Thus, to simulate a longer period of time or a point in time further in the future (e.g., one minute), the same computation is performed until a number of timesteps equaling the period of time have been simulated (e.g., 60 one second time steps to simulate a full minute). The relevant state over time is captured after each iteration to produce a value curve (e.g., the predicted temperature curve at node 1110 over the course of a minute) or a single value is read after the iteration is complete (e.g., the predicted temperature at node 1110 after a minute has passed). The digital twin 1100 in some embodiments is inferenceable by, for example, attaching additional nodes at particular locations such that they obtain information during computation that can then be read as output (or as an intermediate value as described below).

While in some cases the forward activation functions are initially set based on domain knowledge, in some embodiments training data along with a training algorithm are used to further tune the forward activation functions or the backward activation functions to better model the real world systems represented (e.g., to account for unanticipated deviations from the plans such as gaps in venting or variance in equipment efficiency) or adapt to changes in the real world system over time (e.g., to account for equipment degradation, replacement of equipment, remodeling, opening a window, etc.).

In some scenarios, training occurs before active deployment of the digital twin 1100 (e.g., in a lab setting based on a generic training data set) or as a learning process when the digital twin 1100 has been deployed for the system it will model. Sometimes to create training data for active-deployment learning, a controller device 138 observes the data made available from the real-world system being modeled, in some cases data is provided by a sensor system 206 deployed in the environment 130. Some embodiments log this information as a ground truth for use in training examples. To train the digital twin 1100, that controller 138 or system 100 use any of various optimization or supervised learning techniques, such as a gradient descent algorithm that tunes coefficients associated with the forward activation functions or the backward activation functions. The training occurs from time to time in some scenarios, on a scheduled basis, after gathering of a set of new training data of a particular size, in response to determining that one or more nodes or the entire system is not performing adequately (e.g., an error associated with one or more nodes 1110-1132 passed a threshold or passes that threshold for a particular duration of time), in response to manual request from a user, or based on any other trigger. In this way, the digital twin 1100 is adapted 802 to better match its operation to the real world operation of the systems it models, both initially and over the lifetime of its deployment, by tacking itself to the observed operation of those systems.

In some embodiments, the digital twin 1100 is introspectable. That is, the state, behaviors, and properties of the 1110-1132 can be read by another program or a user. This functionality is facilitated by association of each node 1110-1132 to an aspect of the system being modeled. Unlike some neural networks where, due to the fact that neurons don't represent anything particularly and the internal values are largely meaningless on their own (or perhaps exceedingly difficult or impossible to ascribe human meaning), the internal values of the nodes 1110-1132 can easily be interpreted. If an internal “temperature” property is read from node 1110, it is interpreted as the anticipated temperature of the system aspect associated with that node 1110.

Through attachment of a semantic ontology, as described above, the introspectability can be extended to make the digital twin 1100 queryable. That is, ontology can be used as a query language usable to specify what information is desired to be read from the digital twin 1100. In one example, a query is constructed to “read all temperatures from zones having a volume larger than 200 square feet and an occupancy of at least 1.” A process for querying the digital twin 1100 is then able to locate all nodes in the set of nodes 1110-1132 which represent zones that have properties matching the volume and occupancy criteria, and then read out the temperature properties of each such node. The digital twin 1100 in some cases is additionally callable like an API, or via an API, through such processes. With the ability to query and inference, canned (predefined) transactions can be generated and made available to other processes that aren't designed to be familiar with the inner workings of the digital twin 1100. For example, in some cases an “average zone temperature” API function is defined and made available for other elements of the controller or even external devices to use. In some embodiments, further transformation of the data is baked into such canned functions. For example, in some embodiments, the digital twin 1100 does not itself keep track of a “comfort” value, which is defined using various approaches such as the Fanger thermal comfort model. Instead, e.g., a “zone comfort” API function is defined that extracts the relevant properties (such as temperature and humidity) from a specified zone node, computes the comfort according to the desired equation, and provides the response to the calling process or entity.

The digital twin 1100 is merely an example of a possible embodiment and many variations can be employed. In some embodiments, the number and arrangements of the nodes 1110-1132 and edges therebetween are different, either based on the device implementation or based on the environment 130 or building 200 being modeled. For example, a controller deployed in one building sometimes has a digital twin 1100 organized one way to reflect that building and its systems while a controller deployed in a different building has a digital twin 1100 organized in an entirely different way because the building and its systems are different from the first building and therefore indicate a different model. Further, various embodiments of the techniques described herein use alternative types of digital twins. For example, in some embodiments, the digital twin 1100 is not be organized as a neural network and is instead arranged as another type of model for one or more components of the environment 130. In some such embodiments, the digital twin 1100, 132 is or includes a database or other data structure that simply stores descriptions of the system aspects, environmental features, or devices being modeled, such that other software has access to data representative of the real world objects and entities, or their respective arrangements, as the software performs its functions.

Support for the discussion of WSIBP functionality 126 herein is provided under various headings. However, it is all intended to be understood as an integrated and integral part of the present disclosure's discussion of the contemplated embodiments. This disclosure is meant to be understood as a whole. In particular, this disclosure is unlikely to be fully and properly understood during or after only a single top-to-bottom pass through its text. For a full and proper understanding, most if not all readers will also use keyword searches, reference numeral searches, correlation of the specification text with the drawing figures, correlation of the claims with the rest of the text and with the drawing figures, and other nonlinear reading approaches, in addition to reading the full text from top to bottom.

One of skill will recognize that not every part of this disclosure, or any particular details therein, are necessarily required to satisfy legal criteria such as enablement, written description, best mode, novelty, nonobviousness, adequate claim support via technical teachings in the description, inventive step, or industrial applicability. Any apparent conflict with any other patent disclosure, even from the owner of the present subject matter, or any reference external to the present disclosure, has no role in interpreting the claims presented in this patent disclosure. It is in the context of this understanding, which pertains to all parts of the present disclosure, that examples and observations are offered herein.

### Internet of Things

In some embodiments, the system 100 is, or includes, an embedded system such as an Internet of Things system. “IoT” or “Internet of Things” means any networked collection of addressable embedded computing or data generation (e.g., sensors) or actuator nodes. An individual node is referred to as an internet of things device 304 or IoT device 304 or internet of things system 102 or IoT system 102. Such nodes are examples of computer systems 102 as defined herein, and may include or be referred to as a “smart” device, “endpoint”, “chip”, “label”, or “tag”, for example, and IoT may be referred to as a “cyber-physical system”. In the phrase “embedded system” the embedding referred to is the embedding a processor and memory in a device.

### Technical Character

The technical character of embodiments described herein will be apparent to one of ordinary skill in the art, and will also be apparent in several ways to a wide range of attentive readers.

For example, some embodiments address technical activities such as selecting a barrier material without employing human senses or human actions, selecting a barrier thickness without employing human senses or human actions, tuning a simulation without employing human senses or human actions, simulating heat transfer without employing human senses or human actions, and operating HVAC equipment without employing human senses or human actions, which are each an activity deeply rooted in computing technology or HVAC technology or both. The “without employing human senses” and “without employing human actions” qualifiers are stated here explicitly to help prevent misunderstanding by some readers, but they would be understood by one of skill in the art as inherent to the embodiments. These qualifiers shall govern the interpretation of the claims even when not explicitly recited in the claims. To improve readability and reduce disclosure length, these qualifiers are not explicitly repeated throughout this disclosure, but the disclosure should be read as if they were thus repeated.

Moreover, some of the technical mechanisms discussed in this disclosure include, e.g., HVAC equipment, sensors 206, tables and other data structures, and simulations 132. None of these are mental concepts or present merely on paper.

In addition, some of the technical effects discussed include, e.g., more accurate digital representations of buildings, pretraining of neural networks, and conservation of computational resources. Other technical effects are also discussed herein, e.g., in the descriptions of technical benefits and technical challenges.

In short, purely mental processes, activities limited to pen-and-paper, and abstract ideas per se are clearly excluded from the scope of any claimed embodiment. Other advantages based on the technical characteristics of the teachings will also be apparent to one of skill from the description provided.

Different embodiments provide different technical benefits or other advantages in different circumstances, but one of skill informed by the teachings herein will acknowledge that particular technical advantages will likely follow from particular embodiment features or feature combinations, as noted at various points herein.

Any generic or abstract aspects of described embodiments are integrated into a practical application, such as HVAC control systems. The foregoing is an example, not a comprehensive list of all potential practical applications of the present disclosure's teachings.

The present disclosure is focused on providing appropriately specific embodiments whose technical effects fully or partially solve particular technical problems, such as how to approximate barrier thickness and barrier material using sensors, when architectural or construction materials are not sufficient sources of such barrier data, and how to compute barrier thickness or barrier material values for tuning a thermal flow simulation and other building energy modeling. Other systems, devices, and processes involving, e.g., efficiency, reliability, redundancy, or waste are outside the present scope. Accordingly, vagueness, mere abstractness, lack of technical character, and accompanying proof problems are also avoided under a proper understanding of the present disclosure.

### Additional Combinations and Variations

Any combination of logic, components, communications, software, and/or their functional equivalents may also be combined with any of the systems and their variations described above. A process may include any steps described herein in any subset or combination or sequence which is operable. Each variant may occur alone, or in combination with any one or more of the other variants. Each variant may occur with any of the processes and each process may be combined with any one or more of the other processes. Each process or combination of processes, including variants, may be combined with any of the configured storage medium combinations and variants described above.

More generally, one of skill will recognize that not every part of this disclosure, or any particular details therein, are necessarily required to satisfy legal criteria such as enablement, written description, or best mode. Also, embodiments are not limited to the particular scenarios, examples, operating environments, tools, peripherals, process flows, identifiers, naming conventions, notations, control flows, data flows, or other implementation choices described or used herein. Any apparent conflict with any other patent disclosure, even from the owner of the present subject matter, has no role in interpreting the claims presented in this patent disclosure.

### ACRONYMS, ABBREVIATIONS, NAMES, AND SYMBOLS

Some acronyms, abbreviations, names, and symbols are defined below. Others are defined elsewhere herein, or do not require definition here in order to be understood by one of skill.
ALU: arithmetic and logic unit
API: application program interface
BIOS: basic input/output system
CD: compact disc
CPU: central processing unit
DVD: digital versatile disk or digital video disc
FPGA: field-programmable gate array
FPU: floating point processing unit
GDPR: General Data Protection Regulation
GPS: global positioning system
GPU: graphical processing unit
GUI: graphical user interface
IaaS or IAAS: infrastructure-as-a-service
LAN: local area network
OS: operating system
PaaS or PAAS: platform-as-a-service
RAM: random access memory
ROM: read only memory
TPU: tensor processing unit
UEFI: Unified Extensible Firmware Interface
WAN: wide area network

### Some Additional Terminology

Reference is made herein to exemplary embodiments such as those illustrated in the drawings, and specific language is used herein to describe the same. But alterations and further modifications of the features illustrated herein, and additional technical applications of the abstract principles illustrated by particular embodiments herein, which would occur to one skilled in the relevant art(s) and having possession of this disclosure, should be considered within the scope of the claims.

The meaning of terms is clarified in this disclosure, so the claims should be read with careful attention to these clarifications. Specific examples are given, but those of skill in the relevant art(s) will understand that other examples may also fall within the meaning of the terms used, and within the scope of one or more claims. Terms do not necessarily have the same meaning here that they have in general usage (particularly in non-technical usage), or in the usage of a particular industry, or in a particular dictionary or set of dictionaries. Reference numerals may be used with various phrasings, to help show the breadth of a term. Sharing a reference numeral does not mean necessarily sharing every aspect, feature, or limitation of every item referred to using the reference numeral. Omission of a reference numeral from a given piece of text does not necessarily mean that the content of a Figure is not being discussed by the text. The present disclosure asserts and exercises the right to specific and chosen lexicography. Quoted terms are being defined explicitly, but a term may also be defined implicitly without using quotation marks. Terms may be defined, either explicitly or implicitly, here in the Detailed Description and/or elsewhere in the application file.

A “processor” is a thread-processing unit, such as a core in a simultaneous multithreading implementation. A processor includes hardware. A given chip may hold one or more processors. Processors may be general purpose, or they may be tailored for specific uses such as vector processing, graphics processing, signal processing, floating-point arithmetic processing, encryption, I/O processing, machine learning, and so on.

“Kernels” include operating systems, hypervisors, virtual machines, BIOS or UEFI code, and similar hardware interface software.

“Code” means processor instructions, data (which includes constants, variables, and data structures), or both instructions and data. “Code” and “software” are used interchangeably herein. Executable code, interpreted code, and firmware are some examples of code.

“Program” is used broadly herein, to include applications, kernels, drivers, interrupt handlers, firmware, state machines, libraries, and other code written by programmers (who are also referred to as developers) and/or automatically generated.

A “routine” is a callable piece of code which normally returns control to an instruction just after the point in a program execution at which the routine was called. Depending on the terminology used, a distinction is sometimes made elsewhere between a “function” and a “procedure”: a function normally returns a value, while a procedure does not. As used herein, “routine” includes both functions and procedures. A routine may have code that returns a value (e.g., sin(x)) or it may simply return without also providing a value (e.g., void functions).

“Service” as a noun means a consumable program offering, in a cloud computing environment or other network or computing system environment, which provides resources to multiple programs or provides resource access to multiple programs, or does both. A service implementation may itself include multiple applications or other programs.

“Cloud” means pooled resources for computing, storage, and networking which are elastically available for measured on-demand service. A cloud may be private, public, community, or a hybrid, and cloud services may be offered in the form of infrastructure as a service (IaaS), platform as a service (PaaS), software as a service (SaaS), or another service. Unless stated otherwise, any discussion of reading from a file or writing to a file includes reading/writing a local file or reading/writing over a network, which may be a cloud network or other network, or doing both (local and networked read/write). A cloud may also be referred to as a “cloud environment” or a “cloud computing environment”.

“Access” to a computational resource includes use of a permission or other capability to read, modify, write, execute, move, delete, create, or otherwise utilize the resource. Attempted access may be explicitly distinguished from actual access, but “access” without the “attempted” qualifier includes both attempted access and access actually performed or provided.

Herein, activity by a user refers to activity by a user device or activity by a user account or user session, or by software on behalf of a user, or by hardware on behalf of a user. Activity is represented by digital data or machine operations or both in a system. Activity within the scope of any claim based on the present disclosure excludes human actions per se. Software or hardware activity on behalf of a user accordingly refers to software or hardware activity on behalf of a user device or on behalf of a user account or a user session or on behalf of another mechanism or computational artifact, and thus does not bring human behavior per se within the scope of any embodiment or any claim.

“Digital data” means data in a computing system, as opposed to data written on paper or thoughts in a person's mind, for example. Similarly, “digital memory” refers to a non-living device, e.g., computing storage hardware, not to human or other biological memory.

As used herein, “include” allows additional elements (i.e., includes means comprises) unless otherwise stated.

“Optimize” means to improve, not necessarily to perfect. For example, it may be possible to make further improvements in a program or an algorithm which has been optimized.

“Process” is sometimes used herein as a term of the computing science arts, and in that technical sense encompasses computational resource users, which may also include or be referred to as coroutines, threads, tasks, interrupt handlers, application processes, kernel processes, procedures, or object methods, for example. As a practical matter, a “process” in a computing system is a computational entity identified by system utilities such as Windows® Task Manager, Linux® ps, or similar utilities in other operating system environments (marks of Microsoft Corporation, Linus Torvalds, respectively). “Process” may also be used as a patent law term of art, e.g., in describing a process claim as opposed to a system claim or an article of manufacture (configured storage medium) claim. Similarly, “method” is used herein as a patent law term of art (akin to a “method”) but it is also a technical term in the computing science arts (a kind of “routine”). “Process” and “method” in the patent law sense are used interchangeably herein. Those of skill will understand which meaning is intended in a particular instance, and will also understand that a given claimed process or method (in the patent law sense) may sometimes be implemented using one or more processes or methods (in the computing science sense).

“Based on” means computationally based on at least, not based exclusively on. Thus, a calculation based on X depends on at least X, and may also depend on Y. Another way to say this is that the calculation is computed from X.

Throughout this document, use of the optional plural “(s)”, “(es)”, or “(ies)” means that one or more of the indicated features is present. For example, “processor(s)” means “one or more processors” or equivalently “at least one processor”.

“At least one” of a list of items means one of the items, or two of the items, or three of the items, and so on up to and including all N of the items, where the list is a list of N items. The presence of an item in the list does not require the presence of the item (or a check for the item) in an embodiment. For instance, if an embodiment of a system is described herein as including at least one of A, B, C, or D, then a system that includes A but does not check for B or C or D is an embodiment, and so is a system that includes A and also includes B but does not include or check for C or D. Similar understandings pertain to items which are steps or step portions or options in a method embodiment. This is not a complete list of all possibilities; it is provided merely to aid understanding of the scope of “at least one” that is intended herein.

In claims and elsewhere herein, labels such as (a), (b), etc. in a method description are meant to aid legibility of the description, not to impose a strict order or a total ordering of actions in the method. For instance, steps labeled as (a), (b), etc. for convenience may overlap in some embodiments, or interleave in some embodiments. Step performance order may nonetheless be indicated by verb tenses, or be indicated otherwise to one of skill such as when completion of one step is a practical or prerequisite to another step.

For the purposes of United States law and practice, use of the word “step” herein, in the claims or elsewhere, is not intended to invoke means-plus-function, step-plus-function, or 35 United State Code Section 112 Sixth Paragraph/Section 112(f) claim interpretation. Any presumption to that effect is hereby explicitly rebutted.

For the purposes of United States law and practice, the claims are not intended to invoke means-plus-function interpretation unless they use the phrase “means for”. Claim language intended to be interpreted as means-plus-function language, if any, will expressly recite that intention by using the phrase “means for”. When means-plus-function interpretation applies, whether by use of “means for” and/or by a court's legal construction of claim language, the means recited in the specification for a given noun or a given verb should be understood to be linked to the claim language and linked together herein by virtue of any of the following: appearance within the same block in a block diagram of the figures, denotation by the same or a similar name, denotation by the same reference numeral, a functional relationship depicted in any of the figures, a functional relationship noted in the present disclosure's text. For example, if a claim limitation recited a “zac widget” and that claim limitation became subject to means-plus-function interpretation, then at a minimum all structures identified anywhere in the specification in any figure block, paragraph, or example mentioning “zac widget”, or tied together by any reference numeral assigned to a zac widget, or disclosed as having a functional relationship with the structure or operation of a zac widget, would be deemed part of the structures identified in the application for zac widgets and would help define the set of equivalents for zac widget structures.

One of skill will recognize that this disclosure discusses various data values and data structures, and recognize that such items reside in a memory (RAM, disk, etc.), thereby configuring the memory. One of skill will also recognize that this disclosure discusses various algorithmic steps which are to be embodied in executable code in a given implementation, and that such code also resides in memory, and that it effectively configures any general-purpose processor which executes it, thereby transforming it from a general-purpose processor to a special-purpose processor which is functionally special-purpose hardware.

Accordingly, one of skill would not make the mistake of treating as non-overlapping items (a) a memory recited in a claim, and (b) a data structure or data value or code recited in the claim. Data structures and data values and code are understood to reside in a computer system memory, even when a claim does not explicitly recite that residency for each and every data structure or data value or piece of code mentioned. Accordingly, explicit recitals of such residency are not required. However, they are also not prohibited, and one or two select recitals may be present for emphasis, without thereby excluding all the other data values and data structures and code from residency. Likewise, code functionality recited in a claim is understood to configure a computer system hardware processor, regardless of whether that configuring quality is explicitly recited in the claim.

Throughout this document, unless expressly stated otherwise any reference to a step in a process presumes that the step may be performed directly by a party of interest and/or performed indirectly by the party through intervening mechanisms and/or intervening entities, and still lie within the scope of the step. That is, direct performance of the step by the party of interest is not required unless direct performance is an expressly stated requirement. Verbs listed here may overlap in meaning; separate verb names do not dictate separate functionality in every case.

Some people have asserted, outside the present disclosure, that certain verbs indicate human activity, particularly human mental activity. Regardless of their accuracy in other contexts, those assertions are not a correct and accurate basis for the interpretation of any claim supported by the present disclosure, regardless of where they were made. No reference outside the present disclosure to human action associated with a given verb can provide a legally correct basis for the interpretation of any verb recited in any claim supported by the present disclosure. For example, all of the ascertaining, all of the collecting, and all of the selecting described and claimed herein, etc., is artificial activity, not human activity. Relying on external assertions to establish that certain verbs denote human activity elsewhere and therefore also denote mental steps or other human activity within claims is legally incorrect, and is arbitrary and capricious when the specification clearly teaches that such human activity is outside the scope of the claims, as the current specification clearly teaches.

To the extent any human activity is arguably within the scope of any claim based on the present disclosure, that human activity scope is hereby expressly disclaimed and expressly disavowed. Human-machine interaction may be properly noted in a claim for context, e.g., when a claim recites that a user input is received by a computing system. But only the portion of the effective claim scope which is computational and supported herein by the description of computing hardware, interfaces, algorithms, data structures, and/or other non-human mechanisms, as understood by one of skill in the art, is retained.

Whenever reference is made to data or instructions, it is understood that these items configure a computer-readable memory and/or computer-readable storage medium, thereby transforming it to a particular article, as opposed to simply existing on paper, in a person's mind, or as a mere signal being propagated on a wire, for example. For the purposes of patent protection in the United States, a memory or other storage device or other computer-readable storage medium is not a propagating signal or a carrier wave or mere energy outside the scope of patentable subject matter under United States Patent and Trademark Office (USPTO) interpretation of the In re Nuijten case. No claim covers a signal per se or mere energy in the United States, and any claim interpretation that asserts otherwise in view of the present disclosure is unreasonable on its face. Unless expressly stated otherwise in a claim granted outside the United States, a claim does not cover a signal per se or mere energy.

Moreover, notwithstanding anything apparently to the contrary elsewhere herein, a clear distinction is to be understood between (a) computer readable storage media and computer readable memory, on the one hand, and (b) transmission media, also referred to as signal media, on the other hand. A transmission medium is a propagating signal or a carrier wave computer readable medium. By contrast, computer readable storage media and computer readable memory and computer readable storage devices are not propagating signal or carrier wave computer readable media. Unless expressly stated otherwise in the claim, “computer readable medium” means a computer readable storage medium, not a propagating signal per se and not mere energy.

An “embodiment” herein is an example. The term “embodiment” is not interchangeable with “the invention”. Embodiments may freely share or borrow aspects to create other embodiments (provided the result is operable), even if a resulting combination of aspects is not explicitly described per se herein. Requiring each and every permitted combination to be explicitly and individually described is unnecessary for one of skill in the art, and would be contrary to policies which recognize that patent specifications are written for readers who are skilled in the art. Formal combinatorial calculations and informal common intuition regarding the number of possible combinations arising from even a small number of combinable features will also indicate that a large number of aspect combinations exist for the aspects described herein. Accordingly, requiring an explicit recitation of each and every combination would be contrary to policies calling for patent specifications to be concise and for readers to be knowledgeable in the technical fields concerned.

### REMARKS REGARDING REFERENCE NUMERALS

Reference numerals are provided for convenience and in support of the drawing figures and as part of the text of the specification, which collectively describe aspects of embodiments by reference to multiple items. Items which do not have a unique reference numeral may nonetheless be part of a given embodiment. For better legibility of the text, a given reference numeral is recited near some, but not all, recitations of the referenced item in the text. The same reference numeral may be used with reference to different examples or different instances of a given item.

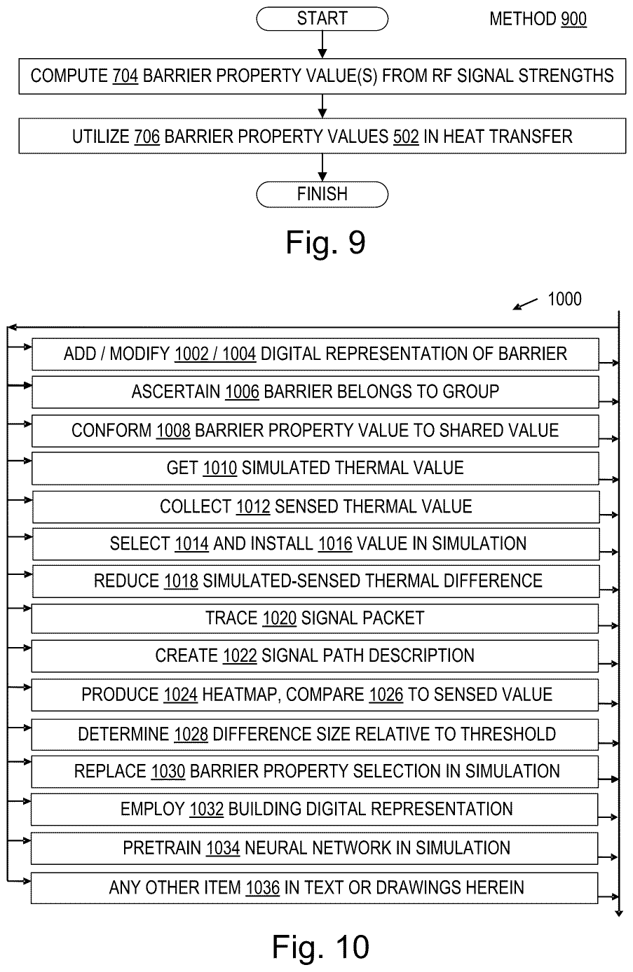

The following remarks pertain to particular reference numerals:
100 enhanced system, i.e., system 102 enhanced with functionality 126 as taught herein
102 computer system, also referred to as a “computational system” or “computing system”, and when in a network may be referred to as a “node”
108 network generally, including, e.g., LANs, WANs, software-defined networks, clouds, and other wired or wireless networks
110 processor or non-empty set of processors; includes hardware
112 computer-readable storage medium, e.g., RAM, hard disks; also referred to as storage device
114 removable configured computer-readable storage medium
116 instructions executable with processor; may be on removable storage media or in other memory (volatile or nonvolatile or both)
118 digital data in a system 102; data structures, values, source code, and other examples are discussed herein
120 kernel(s), e.g., operating system(s), BIOS, UEFI, device drivers; also refers to an execution engine such as a language runtime
124 software, e.g., tools, software applications, web browsers, security controls; computational
126 WISBP functionality (also referred to as functionality 126), e.g., a mechanism which performs or is configured to perform steps 702 and 706, or any mechanism which performs or is configured to perform a sequence of thermal flow activities computed from RF signal strength values as first disclosed herein, or to perform a novel method 1000 first disclosed herein
128 machine in a system 102, e.g., any device having at least a processor 110 and having a distinct identifier such as an IP address or a MAC (media access control) address; may be a physical machine or be a virtual machine implemented on physical hardware
130 operating environment, also referred to as computing environment; includes one or more systems 102
134 cloud, also referred to as cloud environment or cloud computing environment
700 flowchart; 700 also refers to WSIBP methods that are illustrated by or consistent with the FIG. 7 flowchart or any variation of the FIG. 7 flowchart described herein
800 flowchart; 800 also refers to WSIBP methods that are illustrated by or consistent with the FIG. 8 flowchart or any variation of the FIG. 8 flowchart described herein
900 flowchart; 900 also refers to WSIBP methods that are illustrated by or consistent with the FIG. 9 flowchart or any variation of the FIG. 9 flowchart described herein
1000 flowchart; 1000 also refers to WSIBP methods that are illustrated by or consistent with the FIG. 10 flowchart, which incorporates the flowcharts of FIGS. 7 through 9, the steps implicit or express in FIGS. 1 through 6 and 11, and all other steps taught herein, or methods that are illustrated by or consistent with any variation of the FIG. 10 flowchart described herein; all WSIBP method steps are computational or otherwise artificial, not human activity
1036 any step or item discussed in the present disclosure that has not been assigned some other reference numeral; 1036 may thus be shown expressly as a reference numeral for various steps or items or both, and may be added as a reference numeral (in the current disclosure or any subsequent patent application which claims priority to the current disclosure) for various steps or items or both without thereby adding new matter

### Conclusion

Some embodiments leverage radiofrequency signal 300 strength data 302 to improve the accuracy of barrier thermal representations 418 in thermal flow scenarios. Walls 406, floors 408, ceilings 410, windows 412, equipment 414, and furnishings 416 are examples of barriers 204 in a building 200. Barrier properties 502 such as composition material 402 and thickness 404 are computed 704 from radiofrequency signal strength data, and then corresponding thermal characteristics 506 are utilized 706, e.g., when executing 708 a thermal simulation 132, when tuning 802 a neural network 136 or other thermal flow simulation 132, or when operating 710 an HVAC controller 138. A barrier 204 belonging to a group 422 is conformed 1008 in some cases to a shared 504 property value 500 of the group. Threshold 510 condition tests are employed in some cases to select 1014 between material value 402, 500 changes 1004, 1016 and thickness value 404, 500 changes 1004, 1016.

Embodiments are understood to also themselves include or benefit from tested and appropriate security controls and privacy controls such as the General Data Protection Regulation (GDPR), and to comply with all applicable laws and regulations, e.g., the European Union Artificial Intelligence Act (EU AI Act) when applicable. Use of the tools and techniques taught herein can be done together with such controls in compliance with such laws and regulations.

Although particular embodiments are expressly illustrated and described herein as processes, as configured storage media, or as systems, it will be appreciated that discussion of one type of embodiment also generally extends to other embodiment types. For instance, the descriptions of processes in connection with the Figures also help describe configured storage media, and help describe the technical effects and operation of systems and manufactures like those discussed in connection with other Figures. It does not follow that any limitations from one embodiment are necessarily read into another. In particular, processes are not necessarily limited to the data structures and arrangements presented while discussing systems or manufactures such as configured memories.

Those of skill will understand that implementation details may pertain to specific details, such as specific thresholds, topologies, system architectures, and specific operating environments, and thus need not appear in every embodiment. Those of skill will also understand that component identifiers and some other terminology used in discussing details are implementation-specific and thus need not pertain to every embodiment. Nonetheless, although they are not necessarily required to be present here, such details may help some readers by providing context and/or may illustrate a few of the many possible implementations of the technology discussed herein.

With due attention to the items provided herein, including technical processes, technical effects, technical mechanisms, and technical details which are illustrative but not comprehensive of all claimed or claimable embodiments, one of skill will understand that the present disclosure and the embodiments described herein are not directed to subject matter outside the technical arts, or to any idea of itself such as a principal or original cause or motive, or to a mere result per se, or to a mental process or mental steps, or to a business method or prevalent economic practice, or to a mere method of organizing human activities, or to a law of nature per se, or to a naturally occurring thing or process, or to a living thing or part of a living thing, or to a mathematical formula per se, or to isolated software per se, or to a merely conventional computer, or to anything wholly imperceptible or any abstract idea per se, or to insignificant post-solution activities, or to any method implemented entirely on an unspecified apparatus, or to any method that fails to produce results that are useful and concrete, or to any preemption of all fields of usage, or to any other subject matter which is ineligible for patent protection under the laws of the jurisdiction in which such protection is sought or is being licensed or enforced.

Reference herein to an embodiment having some feature X and reference elsewhere herein to an embodiment having some feature Y does not exclude from this disclosure embodiments which have both feature X and feature Y, unless such exclusion is expressly stated herein. All possible negative claim limitations are within the scope of this disclosure, in the sense that any feature which is stated to be part of an embodiment may also be expressly removed from inclusion in another embodiment, even if that specific exclusion is not given in any example herein. The term “embodiment” is merely used herein as a more convenient form of “process, system, article of manufacture, configured computer readable storage medium, and/or other example of the teachings herein as applied in a manner consistent with applicable law.” Accordingly, a given “embodiment” may include any combination of features disclosed herein, provided the embodiment is consistent with at least one claim.

Not every item shown in the Figures need be present in every embodiment. Conversely, an embodiment may contain item(s) not shown expressly in the Figures. Although some possibilities are illustrated here in text and drawings by specific examples, embodiments may depart from these examples. For instance, specific technical effects or technical features of an example may be omitted, renamed, grouped differently, repeated, instantiated in hardware and/or software differently, or be a mix of effects or features appearing in two or more of the examples. Functionality shown at one location may also be provided at a different location in some embodiments; one of skill recognizes that functionality modules can be defined in various ways in a given implementation without necessarily omitting desired technical effects from the collection of interacting modules viewed as a whole. Distinct steps may be shown together in a single box in the Figures, due to space limitations or for convenience, but nonetheless be separately performable, e.g., one may be performed without the other in a given performance of a method.

Reference has been made to the figures throughout by reference numerals. Any apparent inconsistencies in the phrasing associated with a given reference numeral, in the figures or in the text, should be understood as simply broadening the scope of what is referenced by that numeral. Different instances of a given reference numeral may refer to different embodiments, even though the same reference numeral is used. Similarly, a given reference numeral may be used to refer to a verb, a noun, and/or to corresponding instances of each, e.g., a processor 110 may process 110 instructions by executing them.

As used herein, terms such as “a”, “an”, and “the” are inclusive of one or more of the indicated item or step. In particular, in the claims a reference to an item generally means at least one such item is present and a reference to a step means at least one instance of the step is performed. Similarly, “is” and other singular verb forms should be understood to encompass the possibility of “are” and other plural forms, when context permits, to avoid grammatical errors or misunderstandings.

Headings are for convenience only; information on a given topic may be found outside the section whose heading indicates that topic.

All claims and the abstract, as filed, are part of the specification. The abstract is provided for convenience and for compliance with patent office requirements; it is not a substitute for the claims and does not govern claim interpretation in the event of any apparent conflict with other parts of the specification. Similarly, the summary is provided for convenience and does not govern in the event of any conflict with the claims or with other parts of the specification. Claim interpretation shall be made in view of the specification as understood by one of skill in the art; it is not required to recite every nuance within the claims themselves as though no other disclosure was provided herein.

To the extent any term used herein implicates or otherwise refers to an industry standard, and to the extent that applicable law requires identification of a particular version of such as standard, this disclosure shall be understood to refer to the most recent version of that standard which has been published in at least draft form (final form takes precedence if more recent) as of the earliest priority date of the present disclosure under applicable patent law.

While exemplary embodiments have been shown in the drawings and described above, it will be apparent to those of ordinary skill in the art that numerous modifications can be made without departing from the principles and concepts set forth in the claims, and that such modifications need not encompass an entire abstract concept. Although the subject matter is described in language specific to structural features and/or procedural acts, it is to be understood that the subject matter defined in the appended claims is not necessarily limited to the specific technical features or acts described above the claims. It is not necessary for every means or aspect or technical effect identified in a given definition or example to be present or to be utilized in every embodiment. Rather, the specific features and acts and effects described are disclosed as examples for consideration when implementing the claims.

All changes which fall short of enveloping an entire abstract idea but come within the meaning and range of equivalency of the claims are to be embraced within their scope to the full extent permitted by law.

What is claimed is:

1. A method, comprising:
collecting two sensed signal strength values of a radiofrequency signal;
computing a barrier property value from at least the two sensed signal strength values, the barrier property value representing a barrier material or a barrier thickness; and
utilizing the barrier property value in at least one of: executing a computational simulation of heat transfer which employs a digital representation of a building, or operating a heating control mechanism which controls heating of a physical building.

2. The method of claim 1, wherein the barrier property value is associated with a barrier, and utilizing the barrier property value comprises at least one of:
adding a digital representation of the barrier to the digital representation of the building; or
modifying a digital representation of the barrier in the digital representation of the building.

3. The method of claim 1, wherein the barrier property value represents a property value of a barrier, the method comprises ascertaining that the barrier belongs to a group of barriers which share a shared property value, and computing the barrier property value comprises: in response to the ascertaining, conforming the barrier property value to the shared property value.

4. The method of claim 1, wherein the two sensed signal strength values are:
both collected from one sensor, and one of the two sensed signal strength values corresponds to a reflection of the radiofrequency signal; or
collected from at least two sensors, one of the two sensed signal strength values corresponds to the radiofrequency signal prior to a transmission of the radiofrequency signal through the barrier, and the other corresponds to the radiofrequency signal after the transmission of the radiofrequency signal through the barrier.

5. A method, comprising:
collecting two sensed signal strength values of a radiofrequency signal;
computing at least two different barrier property values from at least the two sensed signal strength values, each barrier property value representing a respective barrier material of a barrier or a respective barrier thickness of the barrier; and
utilizing the at least two different barrier property values in tuning a simulation.

6. The method of claim 5, further comprising:
getting a simulated thermal value of a zone which adjoins the barrier, the simulated thermal value produced by the simulation; and
collecting a sensed thermal value of the zone, the sensed thermal value produced by a sensor physically located in the zone;
and wherein tuning the simulation comprises selecting and installing in the simulation whichever of the at least two different barrier property values produces, via the simulation, an updated simulated thermal value of the zone which is closest to the sensed thermal value of the zone.

7. The method of claim 5, wherein computing at least two different barrier property values comprises tracing a packet of the radiofrequency signal to create a path description that includes at least two sensors which are located at respective physical locations at least one meter apart.

8. The method of claim 5, wherein tuning the simulation comprises:
producing a simulation thermal heatmap of thermal values, and comparing a sensed thermal value to the simulation thermal heatmap.

9. The method of claim 5, wherein tuning the simulation comprises: producing a simulation signal strength heatmap of signal strength values, and comparing to the simulation signal strength heatmap at least one of: one of the two sensed signal strength values, or another sensed signal strength value.

10. The method of claim 5, wherein tuning the simulation comprises: determining that a difference between respective ones of the two sensed signal strength values is greater than a predetermined upper threshold, and in response to the determining, updating the simulation by an updated barrier material selection instead of updating the simulation by an updated barrier thickness selection.

11. The method of claim 5, wherein tuning the simulation comprises: determining that a difference between respective ones of the two sensed signal strength values is less than a predetermined lower threshold, and in response to the determining, updating the simulation by an updated barrier thickness selection instead of updating the simulation by an updated barrier material selection.

12. The method of claim 5, wherein tuning the simulation comprises: determining that a difference between respective ones of the two sensed signal strength values is greater than a predetermined upper threshold, and in response to the determining, replacing a first barrier thickness selection by a second barrier thickness selection which is at least ten times the first barrier thickness selection.

13. The method of claim 5, wherein the two sensed signal strength values comprise an incoming sensed signal strength value and an outgoing sensed signal strength value, the incoming sensed signal strength value corresponding to the radiofrequency signal incoming to a wireless communication device, and the outgoing sensed signal strength value corresponding to the radiofrequency signal outgoing from the wireless communication device.

14. The method of claim 5, wherein the radiofrequency signal comprises at least one of: a wireless network signal, a wireless local area network signal, a short-range wireless communication signal, or a wireless personal area network signal.

15. The method of claim 5, wherein the barrier comprises a wall, a floor, a ceiling, a window, a machine, or a furnishing.

16. A computer-readable storage medium configured with data and instructions which upon execution by a processor of a computing system perform a method, the method comprising:
computing a barrier property value from at least two sensed signal strength values, the barrier property value representing a barrier material or a barrier thickness; and
utilizing the barrier property value in at least one of: executing a computational simulation of heat transfer which employs a digital representation of a building, tuning the computational simulation, or operating a heating control mechanism which controls heating of a physical building.

17. The computer-readable storage medium of claim 16, wherein the method computes multiple barrier property values, the method comprises tuning the computational simulation by reducing a distance between a sensed thermal value and a sequence of simulated thermal values, the simulated thermal values produced by the computational simulation from at least respective ones of the multiple barrier property values.

18. The computer-readable storage medium of claim 16, wherein the method comprises tuning the computational simulation, and the tuning comprises pretraining a neural network.

19. The computer-readable storage medium of claim 16, wherein the barrier comprises a floor or a ceiling or both.

20. The computer-readable storage medium of claim 16, wherein the barrier comprises a machine or another piece of equipment located on a floor.
